(19) United States
(12) Patent Application Publication
(10) Pub. No.: US 2025/0096085 A1
(43) Pub. Date: Mar. 20, 2025

(54) CHIP ON FILM PACKAGE AND DISPLAY APPARATUS INCLUDING THE SAME

(71) Applicant: Samsung Electronics Co., Ltd., Suwon-si (KR)

(72) Inventors: Soyoung LIM, Suwon-si (KR); Inho CHOI, Suwon-si (KR)

(73) Assignee: Samsung Electronics Co., Ltd., Suwon-si (KR)

(21) Appl. No.: 18/767,435

(22) Filed: Jul. 9, 2024

(30) Foreign Application Priority Data
Sep. 14, 2023 (KR) 10-2023-0122665

(51) Int. Cl. H01L 23/495; H01L 23/00; H01L 25/065

(52) U.S. Cl. CPC H01L 23/49572; H01L 23/49524; H01L 23/49534; H01L 24/16; H01L 24/32; H01L 24/73; H01L 25/0655; H01L 2224/16245; H01L 2224/32245; H01L 2224/73204

(57) ABSTRACT

A chip on film (COF) package may include a base film including a first side extending in a first horizontal direction, a plurality of conductive lines on an upper surface of the base film and extending in a second horizontal direction perpendicular to the first horizontal direction, a plurality of bridge patterns respectively connected with the plurality of conductive lines and arranged along the first side of the base film, an interlayer insulation layer on the base film and covering a plurality of bridge patterns, and a plurality of input pads on the interlayer insulation layer and respectively connected with the plurality of bridge patterns.

### CROSS-REFERENCE TO RELATED APPLICATION

This application is based on and claims priority under 35 U.S.C. § 119 to Korean Patent Application No. 10-2023-0122665, filed on Sep. 14, 2023 in the Korean Intellectual Property Office, the disclosure of which is incorporated by reference herein in its entirety.

### BACKGROUND

Inventive concepts relate to a semiconductor package and a display apparatus including the same, and more particularly, to a chip on film (COF) package and a display apparatus including the same.

In COF packages, a semiconductor chip may be mounted on a base film, and the mounted semiconductor chip may be electrically connected with an external device through a conductive line in the base film. As the number of input/output (I/O) pads for an electrical connection with an external device increases, a method of securing a pitch between I/O pads in a limited area and securing the reliability of COF packages is needed.

### SUMMARY

Inventive concepts provide a chip on film package and a display apparatus including the same, in which reliability and the degree of integration are enhanced.

According to an embodiment of inventive concepts, a chip on film (COF) package may include a base film including a first side extending in a first horizontal direction; a plurality of conductive lines on an upper surface of the base film and extending in a second horizontal direction, the second horizontal direction being perpendicular to the first horizontal direction; a plurality of bridge patterns respectively connected with the plurality of conductive lines and arranged along the first side of the base film; an interlayer insulation layer on the base film and covering a plurality of bridge patterns; and a plurality of input pads on the interlayer insulation layer and respectively connected with the plurality of bridge patterns.

According to an embodiment of inventive concepts, a chip on film (COF) package may include a base film including a first bonding region, a second bonding region, and a circuit region between the first bonding region and the second bonding region; a plurality of conductive lines on an upper surface of the base film in the circuit region; a protection layer covering the plurality of conductive lines on the upper surface of the base film; a semiconductor chip on the upper surface of the base film in the circuit region, the semiconductor chip connected with one end of a first group of conductive lines among the plurality of conductive lines; a plurality of first bridge patterns on the upper surface of the base film in the first bonding region, the plurality of first bridge patterns arranged in parallel in a first horizontal direction and connected with an other end of the first group of conductive lines; a first interlayer insulation layer covering the plurality of first bridge patterns on the upper surface of the base film in the first bonding region; and a plurality of input pads on the first interlayer insulation layer and arranged in zigzag in the first horizontal direction, and the plurality of input pads respectively being connected with the plurality of first bridge patterns.

According to an embodiment of inventive concepts, a chip on film (COF) package may include a base film including a first bonding region, a second bonding region, and a circuit region between the first bonding region and the second bonding region; a semiconductor chip on the base film in the circuit region; a plurality of bridge patterns on the base film in the first bonding region; a plurality of output pads on the base film in the second bonding region; a plurality of conductive lines on the base film in the circuit region; a protection layer on the base film and covering the plurality of conductive lines in the circuit region; an interlayer insulation layer on the base film and covering the plurality of bridge patterns in the first bonding region; and a plurality of input pads on the interlayer insulation layer and respectively connected with the plurality of bridge patterns. The plurality of conductive lines may include a plurality of input lines respectively connecting the semiconductor chip with the plurality of bridge patterns, a plurality of output lines respectively connecting the semiconductor chip with the plurality of output pads, and a plurality of bypass lines respectively connecting the plurality of bridge patterns with the plurality of output pads.

### BRIEF DESCRIPTION OF THE DRAWINGS

Embodiments will be more clearly understood from the following detailed description taken in conjunction with the accompanying drawings in which:

FIG. 1 is a perspective view illustrating a display apparatus according to embodiments;

FIG. 2A is a plan view illustrating a chip on film (COF) package according to embodiments;

FIG. 2B is a cross-sectional view taken along line Y1-Y1′ of FIG. 2A;

FIG. 2C is an enlarged view of a region EX1 of FIG. 2A;

FIG. 2D is a perspective view illustrating a first bonding region of a COF package according to embodiments;

FIGS. 3A to 3C are perspective views illustrating a first bonding region of a COF package according to some other embodiments;

FIG. 4 is a side cross-sectional view illustrating a display apparatus according to embodiments;

FIG. 5 is a cross-sectional view for describing a COF package according to some embodiments;

FIG. 6A is a plan view for describing a COF package according to some embodiments; and

FIG. 6B is a cross-sectional view taken along line Y2-Y2′ of FIG. 6A.

### DETAILED DESCRIPTION

Hereinafter, embodiments will be described in detail with reference to the accompanying drawings. Like reference numerals refer to like elements in the drawings, and their repeated descriptions are omitted.

Herein, a vertical direction may be defined as a Z direction, and a horizontal direction may be defined as a direction perpendicular to the Z direction. A first horizontal direction and a second horizontal direction may be defined as directions intersecting with each other. The first horizontal direction may be referred to as an X direction, and the second horizontal direction may be referred to as a Y direction. A vertical level may be referred to as a height level with respect to the vertical direction (the Z direction). A horizontal width of an element may be referred to as a length of the element in a horizontal direction, and a vertical length of an element may be referred to as a length of the element in a vertical direction (a Z direction).

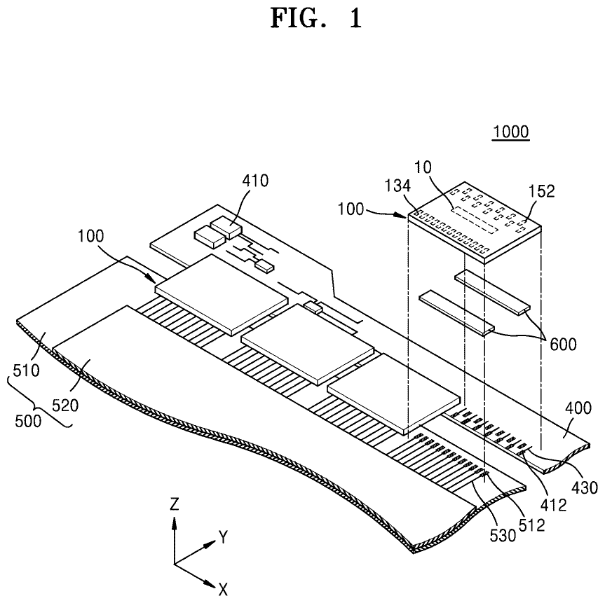

FIG. 1 is a perspective view illustrating a display apparatus 1000 according to embodiments.

Referring to FIG. 1, the display apparatus 1000 may include at least one chip on film (COF) package 100, a driver printed circuit board (PCB) 400, and a display panel 500.

According to embodiments, the COF package 100 may be a package including a semiconductor chip 10, which may be a display driver integrated circuit (DDI). In some embodiments, one semiconductor chip 10 may be disposed in the one COF package 100. In some embodiments, a plurality of semiconductor chips 10 may be disposed in the one COF package 100. For example, the plurality of semiconductor chips 10 may include a source driver chip and/or a gate driver chip.

According to embodiments, the COF package 100 may be disposed between the driver PCB 400 and the display panel 500 and may be connected with each of the driver PCB 400 and the display panel 500. The COF package 100 may receive a signal output from the driver PCB 400 and may transfer the signal to the display panel 500.

According to embodiments, the driver PCB 400 may include one or more driver circuit chips 410 and a plurality of driver connection wirings 430, which apply simultaneously or sequentially apply power and a signal to the COF package 100. Although not shown, the driver PCB 400 may further include a connector (not shown) which receives an external signal. The driver circuit chip 410 may be connected with some of the plurality of driver connection wirings 430 and may process the external signal to output a control signal. The control signal may be provided to the semiconductor chip 10 mounted on the COF package 100.

According to embodiments, the display panel 500 may include a transparent substrate 510, an image region 520 formed on the transparent substrate 510, and a plurality of panel connection wirings 530. The transparent substrate 510 may be, for example, a glass substrate or a flexible substrate. A plurality of pixels provided in the image region 520 may be connected with the plurality of panel connection wirings 530 corresponding thereto and may operate based on a signal provided by the semiconductor chip 10 mounted on the COF package 100. For example, the display panel 500 may be a liquid crystal display (LCD) panel, a light-emitting diode (LED) panel, an organic LED panel, a plasma display panel (PDP), or the like.

According to embodiments, the COF package 100 may be electrically connected with each of the driver connection wiring 430 of the driver PCB 400 and the panel connection wiring 530 of the display panel 500.

In some embodiments, the display panel 500 may include a plurality of panel pads 512 disposed at one end thereof facing the driver PCB 400, and the driver PCB 400 may include a plurality of driver pads 412 disposed at one end thereof facing the display panel 500. The plurality of panel pads 512 may be respectively connected with the plurality of panel connection wirings 530, and the plurality of driver pads 412 may be respectively connected with the plurality of driver connection wirings 430. For example, the plurality of panel pads 512 and the plurality of driver pads 412 may be apart from each other and may be disposed to face each other.

In some embodiments, a plurality of input pads 152 may be formed at one end of the COF package 100, and a plurality of output pads 134 may be formed at the other end of the COF package 100. Each of the plurality of input pads 152 and the plurality of output pads 134 may be connected with a corresponding driver pad 412 of the plurality of driver pads 412 of the driver PCB 400 and a corresponding panel pad 512 of the plurality of panel pads 512 of the display panel 500 by using an anisotropic conductive layer 600.

The anisotropic conductive layer 600 may be, for example, an anisotropic conductive film or an anisotropic conductive paste. The anisotropic conductive layer 600 may have a structure where conductive particles are dispersed in an insulation adhesive layer. Also, the anisotropic conductive layer 600 may have an anisotropic electrical characteristic where electricity flows in only an electrode direction (for example, a Z direction) when connected, and electricity is insulated and does not flow in a direction (for example, an X direction) between adjacent electrodes. When an adhesive is melted by applying heat and pressure to the anisotropic conductive layer 600, conductive particles may be arranged between corresponding electrodes (for example, between the plurality of input pads 152 and the plurality of driver pads 412 and between the plurality of output pads 154 and the plurality of panel pads 512) and may allow electricity to flow, but an adhesive may be filled between adjacent electrodes to allow electricity not to flow.

In some embodiments, a plurality of COF packages 100 may be connected between the driver PCB 400 and the display panel 500. For example, the display panel 500 may be for providing a screen having a large area such as a television (TV), or when the display panel 500 supports a relatively high resolution, the display apparatus 1000 may include a plurality of COF packages 100.

In some embodiments, one COF package 100 may be connected between the driver PCB 400 and the display panel 500. For example, the display panel 500 may be for providing a screen having a small area such as a portable phone, or when the display panel 500 supports a relatively low resolution, the display apparatus 1000 may include one COF package 100.

In some embodiments, the COF package 100 may be connected with only one side of the display panel 500. However, inventive concepts are not limited thereto, and in some other embodiments, one COF package 100 or a plurality of COF packages 100 may be respectively connected with two or more sides of the display panel 500.

Hereinafter, the COF package 100 included in the display apparatus 1000 according to an embodiment will be described in detail.

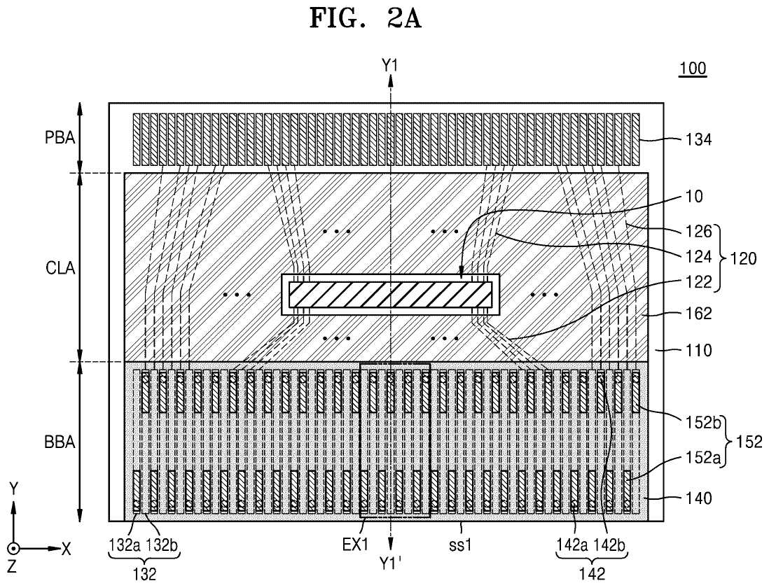

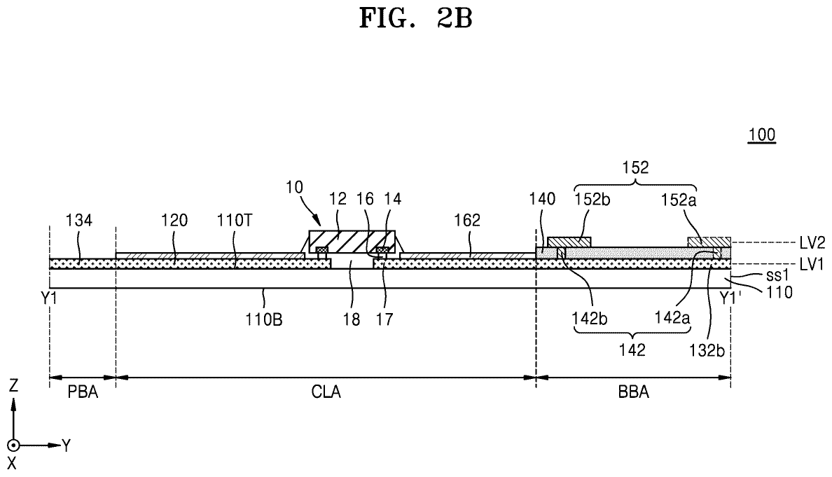

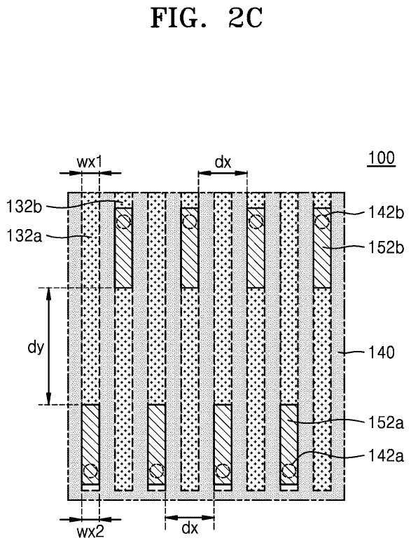

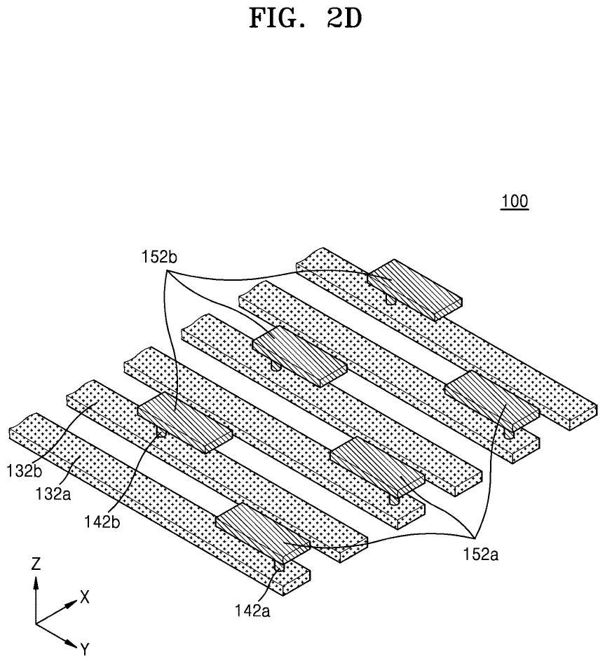

FIG. 2A is a plan view illustrating a COF package 100 according to embodiments. FIG. 2B is a cross-sectional view taken along line Y1-Y1′ of FIG. 2A. FIG. 2C is an enlarged view of a region EX1 of FIG. 2A. FIG. 2D is a perspective view illustrating a first bonding region BBA of the COF package 100 according to embodiments.

Referring to FIGS. 2A to 2D, the COF package 100 may include a base film 110, a plurality of conductive lines 120, a semiconductor chip 10, a plurality of bridge patterns 132, a plurality of input pads 152, and a plurality of output pads 134.

According to embodiments, the base film 110 may include a circuit region CLA, a first bonding region BBA, and a second bonding region PBA. According to embodiments, the first bonding region BBA may be a region which is bonded to the driver PCB 400 (see FIG. 1), and the second bonding region PBA may be a region which is bonded to the display panel 500 (see FIG. 1).

In some embodiments, the base film 110 may have a rectangular shape or a square planar shape, and the first bonding region BBA and the second bonding region PBA may be arranged at both sides of the base film 110 in a second horizontal direction (a Y direction). For example, the first bonding region BBA and the second bonding region PBA may be apart from each other in the second horizontal direction (the Y direction) with the circuit region CLA therebetween. For example, the first bonding region BBA may extend in a first horizontal direction (an X direction) at one side of the circuit region CLA in the second horizontal direction (the Y direction), and the second bonding region PBA may extend in the first horizontal direction (the X direction) at the other side of the circuit region CLA in the second horizontal direction (the Y direction).

In some embodiments, the base film 110 may be a flexible film including polyimide, which is good in coefficient of thermal expansion (CTE) and durability. However, a material of the base film 110 is not limited thereto, and for example, the base film 110 may include epoxy-based resin, acrylic resin, polyether nitrile resin, polyether sulfone resin, polyethylene terephthalate resin, polyethylene naphthalate resin, and a combination thereof.

According to embodiments, the base film 110 may include a first surface 110T and a second surface 110B, which are opposite to each other in a vertical direction (a Z direction).

According to embodiments, the plurality of conductive lines 120 and the semiconductor chip 10 may be disposed in the circular region CLA. According to embodiments, the plurality of bridge patterns 132 and the plurality of input pads 152 may be disposed in the first bonding region BBA, and the plurality of output pads 134 may be disposed in the second bonding region PBA. According to embodiments, the COF package 100 may further include a plurality of chip pads 17 contacting the semiconductor chip 10 in the circuit region CLA.

According to embodiments, the plurality of bridge patterns 132, the plurality of conductive lines 120, the plurality of chip pads 17, and the plurality of output pads 134 may be disposed on the first surface 110T of the base film 110 to contact the first surface 110T of the base film 100. In some embodiments, the plurality of bridge patterns 132, the plurality of conductive lines 120, the plurality of chip pads 17, and the plurality of output pads 134 may be arranged at the same first vertical level LV1.

According to embodiments, the semiconductor chip 10 may be mounted on the first surface 110T of the base film 110. The semiconductor chip 10 may be a DDI which is used to drive the display apparatus 1000 (see FIG. 1). In some embodiments, the semiconductor chip 10 may be a source driver chip which generates an image signal by using a data signal transferred from a timing controller and outputs the image signal to the display panel 500 (see FIG. 1). In some embodiments, the semiconductor chip 10 may be a gate driver chip which outputs a scan signal, including an on/off signal of a transistor, to the display panel 500 (see FIG. 1).

However, the kind of the semiconductor chip 10 is not limited thereto, and for example, when the COF package 100 is coupled to another electronic device instead of the display apparatus 1000, the semiconductor chip 10 may be a chip for driving a corresponding electronic device.

In FIGS. 2A and 2B, the COF package 100 is illustrated as including one semiconductor chip 10, but is not limited thereto. For example, the COF package 100 may include two or more semiconductor chips 10, and each of the semiconductor chips 10 may independently include one or more source driver chips and one or more gate driver chips.

In some embodiments, the semiconductor chip 10 may have a rectangular planar shape which includes a long side in the first horizontal direction (the X direction) and a short side in the second horizontal direction (the Y direction). In some embodiments, a rectangular planar shape of the semiconductor chip 10 may be for increasing the degree of freedom in arrangement/design of the plurality of conductive lines 120, the plurality of input pads 152, and the plurality of output pads 134, which will be described below.

According to embodiments, the semiconductor chip 10 may include a semiconductor substrate 12 and a plurality of bump pads 14. In some embodiments, the semiconductor substrate 12 may include an active surface and an inactive surface, which are opposite to each other. In detail, the semiconductor substrate 12 may be a silicon (Si) wafer including crystalline Si, polycrystalline Si, or amorphous Si. In some embodiments, the semiconductor substrate 12 may include a semiconductor element, such as germanium (Ge), or a compound semiconductor such as silicon carbide (SiC), gallium arsenide (GaAs), indium arsenide (InAs), and indium phosphide (InP). In some embodiments, the plurality of bump pads 14 may include a conductive material. For example, the plurality of bump pads 14 may include metal, such as copper (Cu), aluminum (Al), tungsten (W), titanium (Ti), tantalum (Ta), indium (In), molybdenum (Mo), manganese (Mn), cobalt (Co), zinc (Sn), nickel (Ni), magnesium (Mg), rhenium (Re), beryllium (Be), gallium (Ga), or ruthenium (Ru), or a metal alloy thereof, but are not limited thereto.

In some embodiments, the semiconductor substrate 12 may have a silicon on insulator (SOI) structure. In some embodiments, the semiconductor substrate 12 may include a conductive region, and for example, may include an impurity-doped well or an impurity-doped structure. In some embodiments, the semiconductor substrate 12 may include various device isolation structures such as a shallow trench isolation (STI) structure.

In some embodiments, the semiconductor chip 10 may be mounted on the base film 110 by a flip chip bonding process. For example, a plurality of bump structures 16 such as a solder ball may be disposed on the bump pad 14 exposed at the active surface of the semiconductor chip 10 and the bump structure 16 may be physically and electrically coupled to the plurality of chip pads 17 on the base film 110, and thus, the semiconductor chip 10 may be mounted on the base film 110. Some of the plurality of bump pads 14 may function as an input terminal, and the other of the plurality of bump pads 14 may function as an output terminal.

The plurality of bump structures 16 may be disposed to contact and be electrically connected with the plurality of bump pads 14 and the plurality of chip pads 17, respectively. The semiconductor chip 10 may be supplied with at least one of a control signal, a power signal, and a ground signal for an operation of the semiconductor chip 10, or may be supplied with a data signal, which is to be stored in the semiconductor chip 10, from the outside, or may provide data, stored in the semiconductor chip 10, to the outside. For example, the plurality of bump structures 16 may include a pillar structure, a ball structure, or a solder layer.

According to embodiments, the plurality of conductive lines 120 may be apart from one another and may extend in the second horizontal direction (the Y direction) in the circuit region CLA. In some embodiments, the plurality of conductive lines 120 may each include a portion which extends in a diagonal direction with respect to the first horizontal direction (the X direction) and the second horizontal direction (the Y direction). In some embodiments, the plurality of conductive lines 120 may each include a portion which extends in the first horizontal direction (the X direction).

In some embodiments, the plurality of conductive lines 120 may include an Al foil or a Cu foil, or may be formed by patterning a metal layer formed on the base film 110 by using a casting process, a laminating process, or an electroplating process.

According to embodiments, the plurality of bridge patterns 132 may extend in the second horizontal direction (the Y direction) in the first bonding region BBA and may be arranged in parallel in the first horizontal direction (the X direction). For example, the plurality of bridge patterns 132 may be apart from one another in the first horizontal direction (the X direction). According to embodiments, the plurality of output pads 134 may be arranged in the first horizontal direction (the X direction) in the second bonding region PBA. For example, the plurality of output pads 134 may be apart from one another in the first horizontal direction (the X direction). In some embodiments, each of the plurality of bridge patterns 132 and the plurality of output pads 134 may include metal such as Cu, Al, or W, or an alloy thereof.

According to embodiments, the plurality of conductive lines 120 may include a plurality of input lines 122, a plurality of output lines 124, and a plurality of bypass lines 226. The plurality of input lines 122 may connect a first group of bridge patterns 132 selected from the plurality of bridge patterns 132, and a first group of chip pads 17 selected from the plurality of chip pads 17. The plurality of output lines 124 may connect a first group of output pads 134 selected from the plurality of output pads 134, and a second group of chip pads 17 selected from the plurality of chip pads 17. The plurality of bypass lines 226 may connect a second group of bridge patterns 132 selected from the plurality of bridge patterns 132, and a second group of output pads 134 selected from the plurality of output pads 134.

In some embodiments, both ends of each of the plurality of input lines 122 may individually contact and be connected with the first group of the bridge patterns 132 and the first group of the chip pads 17, both ends of each of the plurality of output lines 124 may individually contact and be connected with the first group of output pads 134 and the second group of chip pads 17, and both ends of each of the plurality of bypass lines 126 may individually contact and be connected with the second group of bridge patterns 132 and the second group of output pads 134.

In some embodiments, each of the plurality of chip pads 17, the plurality of bridge patterns 132, and the plurality of output pads 134 may independently be a portion of a corresponding conductive line 120 of the plurality of conductive lines 120, or may be a portion, plated with tin (Sb), gold (Au), nickel (Ni), or lead (Pb), of a corresponding conductive line 120 of the plurality of conductive lines 120.

In some embodiments, the plurality of conductive lines 120, the plurality of chip pads 17, the plurality of bridge patterns 132, and the plurality of output pads 134 may be provided as one body in the same process. In some embodiments, the plurality of conductive lines 120, the plurality of chip pads 17, the plurality of bridge patterns 132, and the plurality of output pads 134 may include the same material. In some other embodiments, the plurality of chip pads 17, the plurality of bridge patterns 132, and the plurality of output pads 134 may be electrically connected with the plurality of conductive lines 120 and may include a conductive material which is separately formed.

In some embodiments, each of the plurality of chip pads 17 may be a portion of a corresponding input line 122 of the plurality of input lines 122 or a portion of a corresponding output line 124 of the plurality of output lines 124. The plurality of chip pads 17 may be electrically connected with each other through the plurality of bump structures 16 to face the plurality of bump pads 14 in the vertical direction (the Z direction).

In some embodiments, each of the plurality of bridge patterns 132 may be a portion of a corresponding input line 122 of the plurality of input lines 122 or a portion of a corresponding bypass line 126 of the plurality of bypass lines 126. In this case, the portion of each of the plurality of input lines 122 and the portion of each of the plurality of bypass lines 126 may extend from the circuit region CLA to the first bonding region BBA.

In some embodiments, each of the plurality of output pads 134 may be a portion of a corresponding output line 124 of the plurality of output lines 124 or a portion of a corresponding bypass line 126 of the plurality of bypass lines 126. In this case, the portion of each of the plurality of input lines 122 and the portion of each of the plurality of bypass lines 126 may extend from the circuit region CLA to the second bonding region PBA.

According to embodiments, the COH package 100 may include a protection layer 162 covering the plurality of conductive lines 120, on the first surface 110T of the base film 110. The protection layer 162 may limit and/or prevent the plurality of conductive lines 120 from being damaged from an external physical and/or chemical element. The protection layer 162 may include a portion disposed between a plurality of conductive lines 120 apart from each other in a horizontal direction (the X direction and/or the Y direction) and may be configured to insulate the plurality of conductive lines 120 from each other.

In some embodiments, the protection layer 162 may be disposed in the circuit region CLA and may not cover the base film 110 of each of the first bonding region BBA and the second bonding region PBA. In some embodiments, the plurality of output pads 134 of the second bonding region PBA may not be covered by the protection layer 162 and may be exposed. In some embodiments, the plurality of bridge patterns 132 of the first bonding region BBA may not be covered by the protection layer 162 and may be covered by an interlayer insulation layer 140 described below.

In some embodiments, the protection layer 162 may include a solder resist and a dry film resist. In some embodiments, the protection layer 162 may include an insulation layer based on silicon oxide or silicon nitride.

In some embodiments, the protection layer 162 may cover the other region, except a first region with the semiconductor chip 10 mounted thereon, of the circuit region CLA. For example, the first region may be a region, vertically overlapping the semiconductor chip 10, of the base film 110. In some embodiments, the plurality of chip pads 17 may be exposed through the first region and may be electrically connected with the semiconductor chip 10 through the plurality of bump structures 16. A portion of the first surface 110T of the base film 110 may be exposed through the first region.

In some embodiments, an underfill 18 may be disposed between the semiconductor chip 10 and the base film 110, in the first region. In some embodiments, the underfill 18 may cover a side surface and a portion of an upper surface of each of the plurality of chip pads 17. For example, the underfill 18 may be configured to protect the plurality of bump structures 16 and a periphery thereof from an external physical and/or chemical element. In some embodiments, the underfill 18 may be formed by a capillary underfill process. The underfill 18 may include, for example, epoxy resin, but is not limited thereto.

According to embodiments, the COF package 100 may include the interlayer insulation layer 140 covering the plurality of bridge patterns 132, on the first surface of the base film 110. According to embodiments, the interlayer insulation layer 140 may be disposed in the first bonding region BBA. The interlayer insulation layer 140 may include a portion disposed between a plurality of bridge patterns 132 apart from each other in the first horizontal direction (the X direction).

Referring to FIGS. 2C and 2D, the plurality of bridge patterns 132 may include a plurality of first bridge patterns 132a and a plurality of second bridge patterns 132b. In FIG. 2D, for convenience, the interlayer insulation layer 140 is partially omitted and illustrated. According to embodiments, the plurality of first bridge patterns 132a and the plurality of second bridge patterns 132b may have a line shape which extends in the second horizontal direction (the Y direction), with respect to a plane. According to embodiments, the plurality of first bridge patterns 132a and the plurality of second bridge patterns 132b may be alternately arranged one-by-one in the first horizontal direction (the X direction). For example, two adjacent first bridge patterns 132a of the plurality of first bridge patterns 132a may be apart from each other in the first horizontal direction (the X direction) with one second bridge pattern 132b therebetween. According to embodiments, the interlayer insulation layer 140 may be disposed between the plurality of first bridge patterns 132a and the plurality of second bridge patterns 132b.

In some embodiments, end portions of the plurality of first bridge patterns 132a and end portions of the plurality of second bridge patterns 132b may be arranged in parallel in the first horizontal direction (the X direction). For example, the end portions of the plurality of first bridge patterns 132a and the end portions of the plurality of second bridge patterns 132b may be arranged on a virtual straight line parallel to the first horizontal direction (the X direction). In some embodiments, a length of each of the plurality of first bridge patterns 132a in the first horizontal direction (the X direction) may be the same as a length of each of the plurality of second bridge patterns 132b in the second horizontal direction (the Y direction). In some embodiments, the plurality of first bridge patterns 132a and the plurality of second bridge patterns 132b may have similar shapes. For example, the plurality of bridge patterns 132 may be arranged at a certain interval in a first vertical level LV1, and thus, the structural stability of the first bonding region BBA may be enhanced.

According to embodiments, the plurality of input pads 152 may be disposed on the interlayer insulation layer 140. For example, the plurality of input pads 152 may be disposed at a second vertical level LV2, which is higher than the first vertical level LV1. According to embodiments, the plurality of input pads 152 may be disposed to individually and vertically overlap the plurality of bridge patterns 132. For example, the plurality of input pads 152 may be arranged apart from one another.

According to embodiments, the plurality of input pads 152 may be apart from the plurality of bridge patterns 132 in the vertical direction (the Z direction) with the interlayer insulation layer 140 therebetween and may have an independent island shape with respect to a plane.

According to embodiments, the plurality of input pads 152 may include a plurality of first input pads 152a and a plurality of second input pads 152b. In some embodiments, the plurality of first input pads 152a may vertically overlap the plurality of first bridge patterns 132a, and the plurality of second input pads 152b may vertically overlap the plurality of second bridge patterns 132b.

In some embodiments, the base film 110 may include a first side ss1, configuring a boundary of the first bonding region BBA, of both sides thereof in the second horizontal direction (the Y direction). In some embodiments, the plurality of first input pads 152a may be disposed adjacent to the first side ss1 in the first bonding region BBA. In some embodiments, the plurality of first input pads 152a may be arranged in the first horizontal direction (the X direction) along the first side ss1 of the base film 110, on the interlayer insulation layer 140. In some embodiments, the plurality of second input pads 152b may be disposed farther away from the first side ss1 of the base film 110 than the plurality of first input pads 152a. In some embodiments, the plurality of second input pads 152b may be apart from the first side ss1 of the base film 110 with the plurality of first input pads 152a therebetween and may be arranged in the first horizontal direction (the X direction).

In some embodiments, the end portions of the plurality of first bridge patterns 132a and the end portions of the plurality of second bridge patterns 132b may be arranged on a straight line parallel to the first side ss1 of the base film 110.

In some embodiments, the plurality of first input pads 152a may be disposed on the end portions of the plurality of first bridge patterns 132a, and both ends of the plurality of first input pads 152a in the second horizontal direction (the Y direction) may vertically overlap the plurality of first bridge patterns 132a.

In some embodiments, the plurality of second input pads 152b may be arranged apart from the end portions of the plurality of second bridge patterns 132b in the second horizontal direction (the Y direction), with respect to a plane. In some embodiments, the plurality of second bridge patterns 132b may include a portion which is closer to the first side ss1 of the base film 110 than the plurality of second input pads 152b, with respect to a plane. In some embodiments, both ends of the plurality of second input pads 152b in the second horizontal direction (the Y direction) may respectively and vertically overlap the plurality of second bridge patterns 132b.

In some embodiments, the plurality of first input pads 152a may entirely and vertically overlap the plurality of first bridge patterns 132a, and the plurality of second input pads 152b may entirely and vertically overlap the plurality of second bridge patterns 132b.

In some embodiments, the plurality of first input pads 152a and the plurality of second input pads 152b may be alternately arranged one-by-one in zigzag in the first horizontal direction (the X direction). For example, the plurality of first input pads 152a may be respectively disposed apart from the plurality of second input pads 152b in a diagonal direction with respect to the first horizontal direction (the X direction) and the second horizontal direction (the Y direction). In some embodiments, the plurality of first input pads 152a may be arranged in the first horizontal direction (the X direction), and the plurality of second input pads 152b may be arranged in the first horizontal direction (the X direction). For example, with respect to a plane, a first group including a plurality of first input pads 152a and a second group including a plurality of second input pads 152b may be arranged in parallel in the first horizontal direction (the X direction). In some embodiments, with respect to a plane, one second bridge pattern 132b may be disposed between two adjacent first input pads 152a of the plurality of first input pads 152a, and one first bridge pattern 132a may be disposed between two adjacent second input pads 152b of the plurality of second input pads 152b.

According to embodiments, each of the plurality of bridge patterns 132 and a corresponding input pad 152 of the plurality of input pads 152 may be connected with each other through a corresponding connection via 142 of the plurality of connection vias 142 passing through the interlayer insulation layer in the vertical direction (the Z direction). For example, lower surfaces of the plurality of connection vias 142 may respectively contact the plurality of bridge patterns 132, and upper surfaces of the plurality of connection vias 142 may respectively contact the plurality of input pads 152.

According to embodiments, the plurality of connection vias 142 may include a plurality of first connection vias 142a respectively connecting the plurality of first bridge patterns 132a with the plurality of first input pads 152a and a plurality of second connection vias 142b respectively connecting the plurality of second bridge patterns 132b with the plurality of second input pads 152b. In some embodiments, the plurality of first connection vias 142a may be disposed closer to the first side ss1 of the base film 110 than the plurality of second connection vias 142b. The plurality of first connection vias 142a may be arranged apart from one another in the first horizontal direction (the X direction), and the plurality of second connection vias 142b may be arranged apart from one another in the first horizontal direction (the X direction). In some embodiments, the plurality of first connection vias 142a and the plurality of second connection vias 142b may be alternately arranged one-by-one in zigzag in the first horizontal direction (the X direction).

In some embodiments, the plurality of connection vias 142 and the plurality of input pads 152 may each include metal, such as Cu, Al, W, or Ti, or a combination thereof. In some embodiments, a plurality of via holes (not shown) passing through the interlayer insulation layer 140 may be formed, and then, the plurality of connection vias 142 may be formed by filling a conductive material into the plurality of via holes (not shown). Subsequently, the plurality of connection vias 142 may be exposed at the interlayer insulation layer 140 and a mask (not shown) including a pattern hole (not shown) corresponding to the plurality of input pads 152 may be formed, and then, a conductive material may be filled into a portion of the pattern hole (not shown) and the mask (not shown) may be removed, thereby forming the plurality of input pads 152.

Referring to FIG. 2C, the plurality of bridge patterns 132 may have a uniform or a substantially uniform first horizontal width w1 in the first horizontal direction (the X direction). In some embodiments, the plurality of input pads 152 may have a uniform or a substantially uniform second horizontal width w2 in the first horizontal direction (the X direction). In some embodiments, a width of each of the plurality of first bridge patterns 132a in the first horizontal direction (the X direction) may differ from a width of each of the plurality of second bridge patterns 132b in the first horizontal direction (the X direction). In some other embodiments, a width of each of the plurality of first input pads 152a in the first horizontal direction (the X direction) may differ from a width of each of the plurality of second input pads 152b in the first horizontal direction (the X direction).

In some embodiments, the first horizontal width w1 may be the same as or substantially the same as the second horizontal width w2. In some other embodiments, the first horizontal width w1 may differ from the second horizontal width w2. For example, the first horizontal width w1 may be less than the second horizontal width w2.

In some embodiments, a width of the plurality of input pads 152 in the second horizontal direction (the Y direction) may be greater than the second horizontal width w2. For example, the plurality of input pads 152 may include a planar shape including a long side and a short side and an oval shape including a long axis and a short axis, but the embodiment described above is not limited thereto.

In some embodiments, the plurality of first input pads 152a may be arranged apart from one another by a first separation distance dx which is a distance in the first horizontal direction (the X direction). In some embodiments, the plurality of second input pads 152b may be arranged apart from one another by the first separation distance dx in the first horizontal direction (the X direction). In some other embodiments, a separation distance between the plurality of first input pads 152a in the first horizontal direction (the X direction) may differ from a separation distance between the plurality of second input pads 152b in the first horizontal direction (the X direction).

In some embodiments, a first group including the plurality of first input pads 152a and a second group including the plurality of second input pads 152b may be apart from each other by a second separation distance dy in the second horizontal direction (the Y direction). In some embodiments, the second separation width dy may be greater than a width of the plurality of input pads 152 in the second horizontal direction (the Y direction).

A plurality of input pads 152 according to a comparative example may be disposed on a straight line in the first horizontal direction (the X direction) or may be arranged in zigzag in the first horizontal direction (the X direction), but at least some of the plurality of input pads 152 may be disposed at the same vertical level as the plurality of conductive lines 120. A COF package according to the comparative example may have a problem where bonding reliability is reduced because a separation distance between a plurality of input pads 152 adjacent to each other is not sufficiently secured. On the other hand, in the first bonding region BBA, the plurality of input pads 152 according to embodiments may be disposed at a vertical level which is higher than the plurality of bridge patterns 132, and the plurality of first input pads 152a may be disposed apart from the plurality of second input pads 152b in the second horizontal direction (the Y direction). Therefore, regardless of a pitch between the plurality of conductive lines 120 and the plurality of bridge patterns 132 disposed at the first vertical level LV1, a pitch between the plurality of input pads 152 may be independently secured at the second vertical level LV2, and the reliability of the COF package 100 may be enhanced.

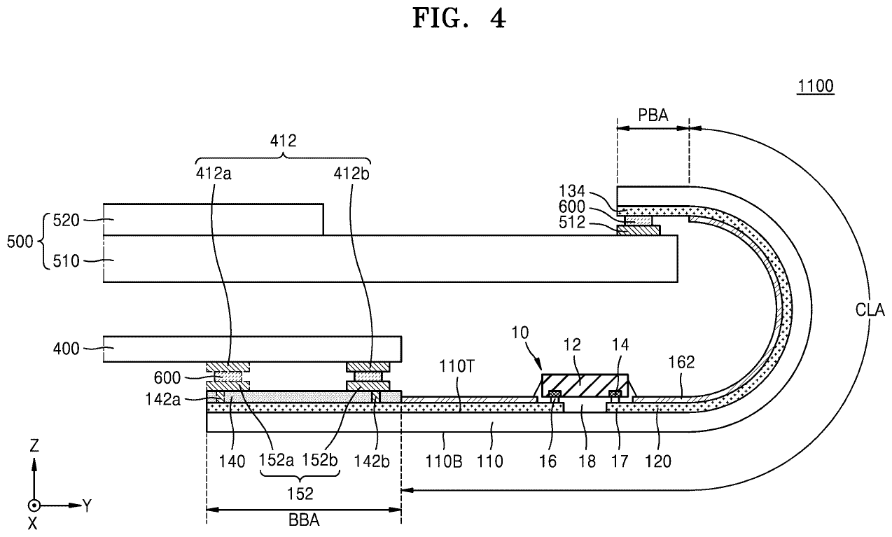

Also, the plurality of conductive lines 120, the plurality of bridge patterns 132, the plurality of output pads 134, and the plurality of input pads 152 of the COF package 100 according to embodiments may all be disposed on the first surface of the base film 110. Accordingly, when the COF package 100 is applied to a display apparatus 1100 which will be described below with reference to FIG. 4, the stress of a bending region may be reduced, and thus, the structural stability of the COF package 100 and the display apparatus 1100 may be enhanced.

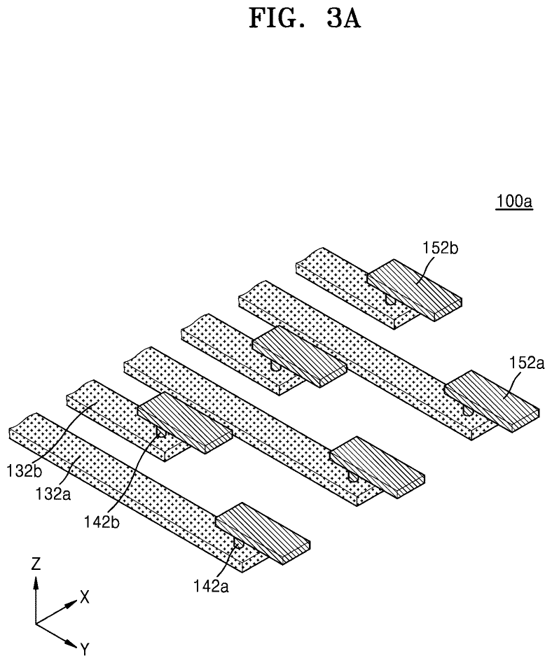

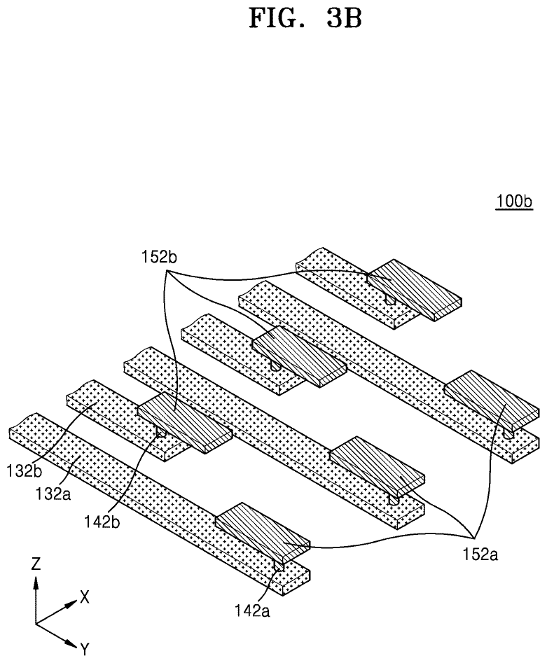

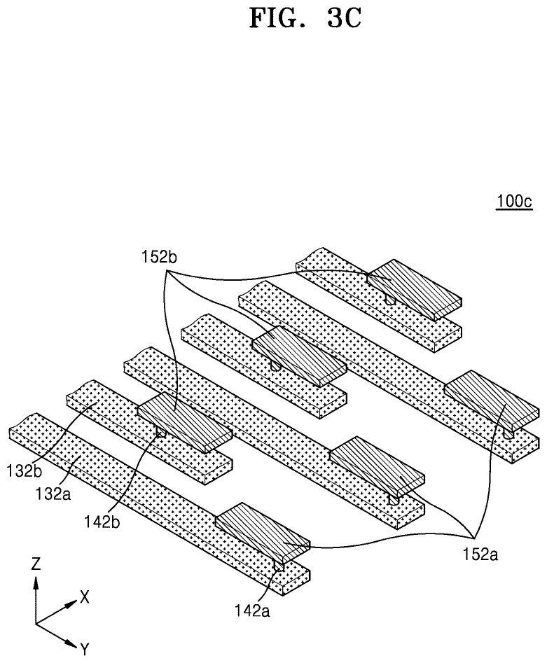

FIGS. 3A to 3C are perspective views illustrating partial portions of the first bonding region BBA of COF packages 100a, 100b, and 100c according to some other embodiments. In detail, FIGS. 3A to 3C illustrate a portion corresponding to FIG. 2D. In FIGS. 3A to 3C, the same reference numerals as FIGS. 1 and 2A to 2D refer to like members, and detailed descriptions thereof are omitted.

Referring to FIG. 3A, a plurality of input pads 152 of the COF package 100a may respectively include portions which do not vertically overlap a plurality of bridge patterns 132. In some embodiments, the plurality of input pads 152 and the plurality of bridge patterns 132 may vertically overlap one another at portions connected with one another through a plurality of connection vias 142. In some embodiments, one end of each of the plurality of input pads 152 in a second horizontal direction (a Y direction) may vertically overlap a corresponding bridge pattern 132 of the plurality of bridge patterns 132, and the other end of each of the plurality of input pads 152 in the second horizontal direction (the Y direction) may not vertically overlap the plurality of bridge patterns 132.

According to some embodiments, lengths of the plurality of bridge patterns 132 in the second horizontal direction (the Y direction) may differ. In some embodiments, end portions of the plurality of bridge patterns 132 may not be arranged on a straight line in a first horizontal direction (an X direction). In some embodiments, end portions of a plurality of first bridge patterns 132a may protrude toward a first side ss1 of a base film 110 (see FIG. 2A) from end portions of a plurality of second bridge patterns 132b. For example, the end portions of the plurality of first bridge patterns 132a may be arranged on a virtual first straight line extending in the first horizontal direction (the X direction), and the end portions of the plurality of second bridge patterns 132b may be arranged on a virtual second straight line which extends in the first horizontal direction (the X direction) and is parallel to the first straight line.

Referring to FIG. 3B, comparing with the COF package 100a according to FIG. 3A, a plurality of first bridge patterns 132a of the COF package 100b may more extend toward the first side ss1 (see FIG. 2A) in a second horizontal direction (a Y direction) and may vertically overlap a plurality of first input pads 152a. For example, all of both ends of the plurality of first input pads 152a of the COF package 100b in the second horizontal direction (the Y direction) may vertically overlap a corresponding first bridge pattern 132a.

In some embodiments, end portions of the plurality of first input pads 152a and end portions of the plurality of first bridge patterns 132a may be aligned in a vertical direction (a Z direction).

Referring to FIG. 3C, comparing with the COF package 100b according to FIG. 3B, a plurality of second bridge patterns 132b of the COF package 100c may more extend toward the first side ss1 (see FIG. 2A) in a second horizontal direction (a Y direction) and may vertically overlap a plurality of second input pads 152b. For example, all of both ends of the plurality of second input pads 152b of the COF package 100c in the second horizontal direction (the Y direction) may vertically overlap a corresponding second bridge pattern 132b.

In some embodiments, end portions of the plurality of second input pads 152b and end portions of the plurality of second bridge patterns 132b may be aligned in a vertical direction (a Z direction).

FIG. 4 is a side cross-sectional view illustrating a display apparatus 1100 according to embodiments. In detail, in the display apparatus 1100 of FIG. 4, a driver PCB 400 and a display panel 500 may be bonded to a COF package 100 in the display apparatus 1000 illustrated in FIG. 1, and then, the COF package 100 may be bent so that the driver PCB 400 overlaps the display panel 500 in a vertical direction (a Z direction). In FIG. 4, the same reference numerals as FIGS. 1 and 2A to 2D refer to like members, and detailed descriptions thereof are omitted.

In some embodiments, a first bonding region BBA of the COF package 100 may be disposed to face a portion of the driver PCB 400 in the vertical direction (the Z direction), and a second bonding region PBA of the COF package 100 may be disposed to face a portion of the display panel 500 in the vertical direction (the Z direction).

In some embodiments, a plurality of input pads 152 of the COF package 100 may be electrically connected with a plurality of driver pads 412 through an anisotropic conductive layer 600. For example, the anisotropic conductive layer 600 may be disposed between the plurality of input pads 152 and the plurality of driver pads 412 and may contact each of the plurality of input pads 152 and the plurality of driver pads 412.

In some embodiments, the plurality of driver pads 412 may have a structure corresponding to the plurality of input pads 152 and may be aligned with the plurality of input pads 152 in the vertical direction (the Z direction). For example, the plurality of driver pads 412 may include a plurality of first driver pads 412a connected with a plurality of first input pads 152a and a plurality of second driver pads 412b connected with a plurality of second input pads 152b. Although not shown, the plurality of first driver pads 412a and the plurality of second driver pads 412b may be alternately arranged in zigzag in a first horizontal direction (an X direction).

In some embodiments, a plurality of output pads 134 of the COF package 100 may be electrically connected with a plurality of panel pads 512 through an anisotropic conductive layer 600. For example, the anisotropic conductive layer 600 may be disposed between the plurality of output pads 134 and the plurality of panel pads 512 and may contact each of the plurality of output pads 134 and the plurality of panel pads 512.

In some embodiments, the plurality of panel pads 512 may have a structure corresponding to the plurality of output pads 134 and may be aligned with the plurality of output pads 134 in the vertical direction (the Z direction). For example, although not shown, the plurality of panel pads 512 may be arranged apart from one another in the first horizontal direction (the X direction).

In some embodiments, the COF package 100 may receive a signal, output from the driver PCB 400, through a conductive line 120 and may transfer the signal to the display panel 500 through the conductive line 120.

A plurality of conductive lines 120, a plurality of bridge patterns 132, a plurality of input pads 152, and a plurality of output pads 134 of the COF package 100 according to embodiments may be disposed on a first surface 110T of the base film 110, and a second surface 110B of the base film 110 may be exposed to the outside. In some embodiments, a portion of a circuit region CLA may be bent and the COF package 100 may be applied to the display apparatus 1100, and in this case, the portion of the circuit region CLA may have a relatively thin thickness and may thus be easily bent by small stress applied thereto, thereby enhancing the structural stability of the display apparatus 1100 including the COF package 100.

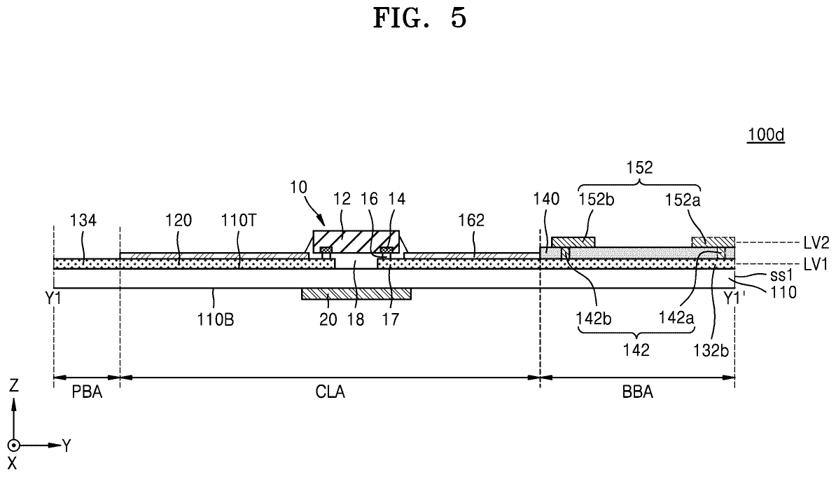

FIG. 5 is a cross-sectional view for describing a COF package 100d according to some embodiments. In detail, FIG. 5 illustrates a portion corresponding to FIG. 2B. In FIG. 5, the same reference numerals as FIGS. 1 and 2A to 2D refer to like members, and detailed descriptions thereof are omitted. FIG. 5 may have a difference with FIG. 2B in that the COF package 100d further includes a stiffener 20.

Referring to FIG. 5, the COF package 100d may further include the stiffener 20 which vertically overlaps a semiconductor chip 10, on a second surface 110B of a base film 110. The stiffener 20 may be disposed under the semiconductor chip 10, and when the COF package 100 is bent and applied to the display apparatus 1100, the stiffener 20 may limit and/or prevent the semiconductor chip 10 from being damaged by stress or from being detached from the COF package 100.

In some embodiments, the stiffener 20 may include an insulating material, but is not limited thereto. For example, the stiffener 20 may include metal and for example, may include at least one of Cu, Ni, and stainless steel. In some embodiments, an adhesive film (not shown) may be disposed between the stiffener 20 and the base film 110, and the stiffener 20 may be disposed on the second surface 110B of the base film 110 by using the adhesive film (not shown). The adhesive film (not shown) may include an insulating material or a material capable of maintaining electrical insulating properties. The adhesive film (not shown) may include, for example, epoxy resin, mineral oil, grease, gap filler putty, phase change gel, phase change material pads, or particle filled epoxy.

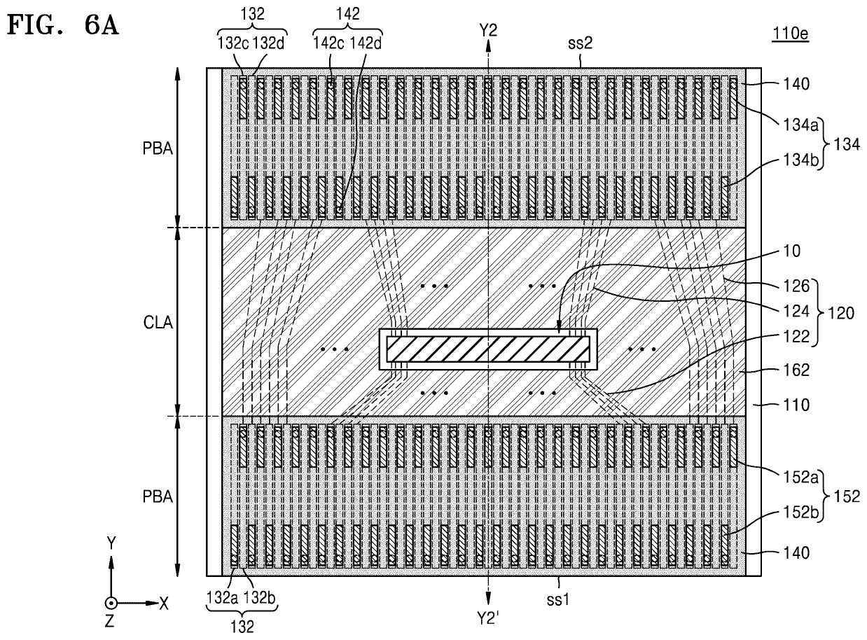

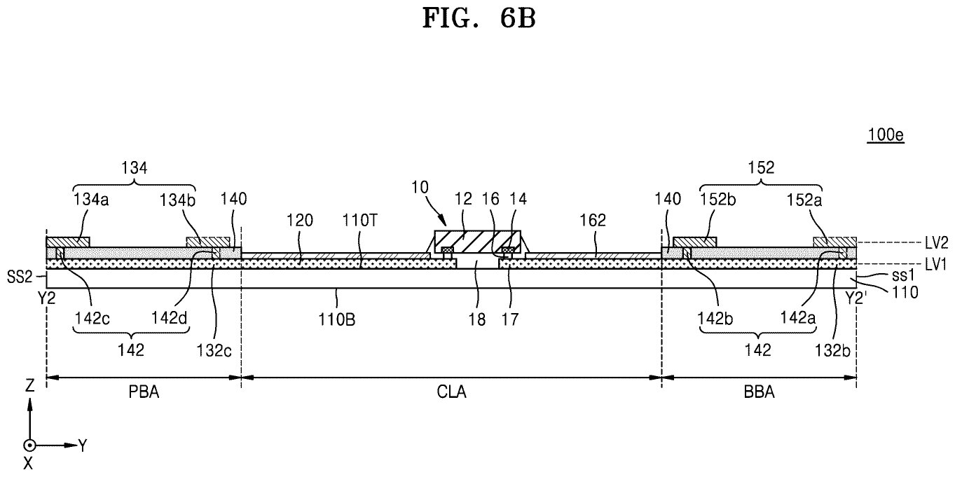

FIG. 6A is a plan view for describing a COF package 100e according to some embodiments. FIG. 6B is a cross-sectional view taken along line Y2-Y2′ of FIG. 6A. In FIGS. 6A and 6B, the same reference numerals as FIGS. 1 and 2A to 2D refer to like members, and detailed descriptions thereof are omitted. In the difference between the COF package 100e described above with reference to FIGS. 6A and 6B and the COF package 100 described above with reference to FIGS. 2A to 2D, the COF package 100e may further include a plurality of third bridge patterns 132c and a plurality of fourth bridge patterns 132d, which are disposed at a first vertical level LV1 in a second bonding region PBA, and a plurality of output pads 134 may be disposed at a second vertical level LV2.

Referring to FIGS. 6A and 6B, the second bonding region PBA of the COF package 100e may have a structure similar to that of the first bonding region BBA.

In some embodiments, a plurality of bridge patterns 132 of the COF package 100e may include the plurality of third bridge patterns 132c and the plurality of fourth bridge patterns 132d, which are disposed on a first surface 110T of a base film 110 in the second bonding region PBA. In some embodiments, the plurality of third bridge patterns 132c and the plurality of fourth bridge patterns 132d may be disposed at the first vertical level LV1, which is the same vertical level as the conductive line 120.

In some embodiments, each of the plurality of third bridge patterns 132c and the plurality of fourth bridge patterns 132d may individually contact and be connected with some of a plurality of output lines 123 or a plurality of bypass lines 126.

In some embodiments, each of the plurality of third bridge patterns 132c and the plurality of fourth bridge patterns 132d may be a portion of a corresponding conductive line 120 of the plurality of conductive lines 120 connected thereto. In this case, some of the plurality of conductive lines 120 may extend to the second bonding region PBA in the circuit region CLA.

In some embodiments, the plurality of third bridge patterns 132c and the plurality of fourth bridge patterns 132d may be alternately arranged in a first horizontal direction (an X direction) in the second bonding region PBA. In some embodiments, one end portion of each of the plurality of third bridge patterns 132c and one end portion of each of the plurality of fourth bridge patterns 132d may be arranged along a second side ss2, which is opposite to a first side ss1, of the base film 110.

In some embodiments, an interlayer insulation layer 140 may cover a plurality of first bridge patterns 132a and a plurality of second bridge patterns 132b in a first bonding region BBA and may cover the plurality of third bridge patterns 132c and the plurality of fourth bridge patterns 132d in the second bonding region PBA.

In some embodiments, in the second bonding region PBA, a plurality of output pads 134 may be disposed at the same second vertical level LV2 as a plurality of input pads 152, on the interlayer insulation layer 140. In some embodiments, the plurality of output pads 134 may include a first output pad 134a, which at least partially and vertically overlaps the plurality of third bridge patterns 132c, and a second output pad 134b, which at least partially and vertically overlaps the plurality of fourth bridge patterns 132d. The plurality of output pads 134 may be disposed apart from one another on the interlayer insulation layer 140 and may have an independent island shape, with respect to a plane.

In some embodiments, a plurality of first output pads 134a may be arranged in the first horizontal direction (the X direction) along the second side ss2 in the second bonding region PBA. In some embodiments, a plurality of second output pads 134b may be disposed farther away from the second side ss2 than the plurality of first output pads 134a in a second horizontal direction (a Y direction).

In some embodiments, the plurality of first output pads 134a may be respectively disposed apart from the plurality of second output pads 134b in a diagonal direction with respect to the first horizontal direction (the X direction) and the second horizontal direction (the Y direction). In some embodiments, the plurality of first output pads 134a and the plurality of second output pads 134b may be alternately arranged one-by-one in zigzag in the first horizontal direction (the X direction). For example, with respect to a plane, a first group including a plurality of first output pads 134a and a second group including a plurality of second output pads 134b may be arranged in parallel in the first horizontal direction (the X direction). In some embodiments, with respect to a plane, one fourth bridge pattern 132d may be disposed between two adjacent first output pads 134a of the plurality of first output pads 134a, and one third bridge pattern 132c may be disposed between two adjacent second output pads 134b of the plurality of second output pads 134b.

According to embodiments, a plurality of connection vias 142 may include a plurality of third connection vias 142c and a plurality of fourth connection vias 142d, which pass through the interlayer insulation layer 140 in a vertical direction (a Z direction) in the second bonding region PBA. According to embodiments, the plurality of third bridge patterns 132c may respectively and individually contact and be connected with the plurality of first output pads 134a through the plurality of third connection vias 142c, and the plurality of fourth bridge patterns 132d may respectively and individually contact and be connected with the plurality of second output pads 134b through the plurality of fourth connection vias 142d.

According to embodiments, the COF package 100e may include a plurality of input pads 152 and a plurality of output pads 134, which have an independent island shape with respect to a plane and are disposed at the second vertical level LV2 in each of the first bonding region BBA and the second bonding region PBA. Accordingly, even when the COF package 100e is applied to a display apparatus where a pitch between I/O pads of each of the driver PCB 400 (see FIG. 1) and the display panel 500 (see FIG. 1) is very narrow, high electrical reliability and structural stability may be secured.

Hereinabove, embodiments have been described in the drawings and the specification. Embodiments have been described by using the terms described herein, but this has been merely used for describing inventive concepts and has not been used for limiting a meaning or limiting the scope of inventive concepts defined in the following claims. Therefore, it may be understood by those of ordinary skill in the art that various modifications and other equivalent embodiments may be implemented from embodiments of inventive concepts. Accordingly, the spirit and scope of inventive concepts may be defined based on the spirit and scope of the following claims.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A chip on film (COF) package comprising:
a base film including a first side extending in a first horizontal direction;
a plurality of conductive lines on an upper surface of the base film and extending in a second horizontal direction, the second horizontal direction being perpendicular to the first horizontal direction;
a plurality of bridge patterns respectively connected with the plurality of conductive lines and arranged along the first side of the base film;
an interlayer insulation layer on the base film and covering a plurality of bridge patterns; and
a plurality of input pads on the interlayer insulation layer and respectively connected with the plurality of bridge patterns.

2. The COF package of claim 1, wherein
the plurality of conductive lines are at a first vertical level, and
the plurality of input pads are at a second vertical level, and
the second vertical level is higher than the first vertical level.

3. The COF package of claim 1, wherein the plurality of input pads have an island shape on the interlayer insulation layer.

4. The COF package of claim 1, wherein the plurality of input pads are arranged in zigzag in the first horizontal direction.

5. The COF package of claim 1, wherein
the plurality of input pads comprise a plurality of first input pads and a plurality of second input pads,
the plurality of first input pads are adjacent to the first side of the base film,
the plurality of second input pads are farther away from the first side of the base film in the second horizontal direction than the plurality of first input pads, and
the plurality of first input pads and the plurality of second input pads are arranged in parallel in the first horizontal direction.

6. The COF package of claim 1, wherein each of the plurality of bridge patterns is a portion of a corresponding conductive line of the plurality of conductive lines.

7. The COF package of claim 1, wherein
the plurality of bridge patterns extend in parallel in the second horizontal direction,
end portions of the plurality of bridge patterns face the first side of the base film, and
the end portions of the plurality of bridge patterns are arranged in parallel in the first horizontal direction.

8. The COF package of claim 1, wherein
the plurality of bridge patterns extend in parallel in the second horizontal direction, and
lengths of some of the plurality of bridge patterns in the second horizontal direction differ from lengths of others of the plurality of bridge patterns in the second horizontal direction.

9. The COF package of claim 1, wherein the plurality of input pads entirely and vertically overlap the plurality of bridge patterns.

10. The COF package of claim 1, further comprising:
a plurality of connection vias passing through the interlayer insulation layer in a vertical direction, wherein
the plurality of connection vias respectively contact the plurality of bridge patterns and the plurality of input pads, and
the plurality of connection vias are arranged in zigzag in the first horizontal direction.

11. A chip on film (COF) package comprising:
a base film including a first bonding region, a second bonding region, and a circuit region between the first bonding region and the second bonding region;
a plurality of conductive lines on an upper surface of the base film in the circuit region;
a protection layer covering the plurality of conductive lines on the upper surface of the base film;
a semiconductor chip on the upper surface of the base film in the circuit region, the semiconductor chip connected with one end of a first group of conductive lines among the plurality of conductive lines;
a plurality of first bridge patterns on the upper surface of the base film in the first bonding region, the plurality of first bridge patterns arranged in parallel in a first horizontal direction and connected with an other end of the first group of conductive lines;
a first interlayer insulation layer covering the plurality of first bridge patterns on the upper surface of the base film in the first bonding region; and
a plurality of input pads on the first interlayer insulation layer and arranged in zigzag in the first horizontal direction, and the plurality of input pads respectively being connected with the plurality of first bridge patterns.

12. The COF package of claim 11, wherein a portion of each of the plurality of first bridge patterns vertically overlaps a corresponding input pad of the plurality of input pads.

13. The COF package of claim 11, wherein the plurality of input pads have an island shape on the first interlayer insulation layer.

14. The COF package of claim 11, further comprising:
a plurality of output pads on the upper surface of the base film in the second bonding region, the protection layer exposing the plurality of output pads by not covering the plurality of output pads, wherein
the plurality of output pads are connected with the semiconductor chip through a second group of conductive lines among the plurality of conductive lines, and
the plurality of output pads are at a same vertical level as the plurality of first bridge patterns.

15. The COF package of claim 11, further comprising:
a plurality of second bridge patterns on the upper surface of the base film in the second bonding region and arranged in parallel in the first horizontal direction;
a second interlayer insulation layer covering the plurality of second bridge patterns on the upper surface of the base film; and
a plurality of output pads on the second interlayer insulation layer and arranged in zigzag in the first horizontal direction, the plurality of output pads respectively being connected with the plurality of second bridge patterns.

16. The COF package of claim 11, further comprising:
a stiffener on a lower surface of the base film, wherein
the lower surface of the base film is opposite the upper surface of the base film, and
the stiffener vertically overlaps the semiconductor chip.

17. A chip on film (COF) package comprising:
a base film including a first bonding region, a second bonding region, and a circuit region between the first bonding region and the second bonding region;
a semiconductor chip on the base film in the circuit region;
a plurality of bridge patterns on the base film in the first bonding region;
a plurality of output pads on the base film in the second bonding region;
a plurality of conductive lines on the base film in the circuit region,
the plurality of conductive lines including a plurality of input lines respectively connecting the semiconductor chip with the plurality of bridge patterns, a plurality of output lines respectively connecting the semiconductor chip with the plurality of output pads, and a plurality of bypass lines respectively connecting the plurality of bridge patterns with the plurality of output pads;
a protection layer on the base film and covering the plurality of conductive lines in the circuit region;
an interlayer insulation layer on the base film and covering the plurality of bridge patterns in the first bonding region; and
a plurality of input pads on the interlayer insulation layer and respectively connected with the plurality of bridge patterns.

18. The COF package of claim 17, wherein the plurality of output pads, the plurality of conductive lines, and the plurality of bridge patterns are at a first vertical level.

19. The COF package of claim 18, wherein
the plurality of input pads are at a second vertical level, and
the second vertical level is higher than the first vertical level.

20. The COF package of claim 17, wherein
the plurality of bridge patterns are arranged in parallel in a first horizontal direction,
the plurality of input pads are arranged in zigzag in the first horizontal direction, and
the plurality of input pads vertically overlap the plurality of bridge patterns, respectively.
